(19) United States
(12) Patent Application Publication
(10) Pub. No.: US 2026/0150628 A1
(43) Pub. Date: May 28, 2026

(54) SEMICONDUCTOR PACKAGE STRUCTURE AND METHOD OF MANUFACTURING THE SAME

(71) Applicant: TAIWAN SEMICONDUCTOR MANUFACTURING COMPANY LTD., HSINCHU (TW)

(72) Inventors: YI-TING RUAN, HSINCHU COUNTY (TW); CHI-KAO TANG, HSINCHU CITY (TW); CHIA-CHUN YEH, TAOYUAN CITY (TW); YUAN-YAO CHANG, KAOHSIUNG CITY (TW); YI-FENG CHANG, NEW TAIPEI CITY (TW)

(21) Appl. No.: 18/956,039

(22) Filed: Nov. 22, 2024

(51) Int. Cl. H01L 21/66; H01L 23/00; H01L 25/10

(52) U.S. Cl. CPC H10P 74/273; H10W 70/09; H10W 70/60; H10W 70/6528; H10W 90/00; H10W 90/10; H10W 90/724

(57) ABSTRACT

A semiconductor package is provided. The semiconductor package includes a plurality of metal stacks stacking on die units. Each of the plurality of metal stacks includes at least one metallization layer. The at least one metallization layer electrically connects the die units through a via portion and includes a signal pad, a connecting pad and a testing pad electrically connecting with each other.

### BACKGROUND

Electronic equipments using semiconductor devices are essential for many modern applications. With the advancement of electronic technology, the semiconductor devices are becoming increasingly smaller in size while having greater functionality and greater amounts of integrated circuitry. Due to the miniaturized scale of the semiconductor device, a wafer level packaging (WLP) is widely used for its low cost and relatively simple manufacturing operations. During the WLP operation, a number of semiconductor components are assembled on the semiconductor device. Furthermore, numerous manufacturing operations are implemented within such a small semiconductor device.

However, the manufacturing operations of the semiconductor device involve many steps and operations on such a small and thin semiconductor device. The manufacturing of the semiconductor device in a miniaturized scale becomes more complicated. An increase in a complexity of manufacturing the semiconductor device may cause deficiencies such as poor electrical interconnection, delamination of components, or other issues, resulting in a high yield loss of the semiconductor device. As such, there are many challenges for modifying a structure of the semiconductor devices and improving the manufacturing operations.

### BRIEF DESCRIPTION OF THE DRAWINGS

Aspects of the present disclosure are best understood from the following detailed description when read with the accompanying figures. It should be noted that, in accordance with the standard practice in the industry, various features are not drawn to scale. In fact, the dimensions of the various features may be arbitrarily increased or reduced for clarity of discussion.

FIG. 1 illustrates a top view of a semiconductor package, in accordance with some embodiments of the present disclosure.

FIG. 2 illustrates a cross-sectional side view of a semiconductor package, in accordance with some embodiments of the present disclosure.

FIG. 3 illustrates a perspective view of a redistribution structure connecting an external connector of a semiconductor package, in accordance with some embodiments of the present disclosure.

FIG. 4 illustrates an exploded view of the semiconductor package shown in FIG. 3, in accordance with some embodiments of the present disclosure.

FIG. 5 illustrates a top view of the semiconductor package shown in FIG. 3, in accordance with some embodiments of the present disclosure.

FIGS. 6A to 6C illustrate perspective views of a first metallization layer, a second metallization layer and a third metallization layer, respectively, in the semiconductor package shown in FIG. 3, in accordance with some embodiments of the present disclosure.

FIG. 7 illustrates a perspective view of a redistribution structure connecting an external connector of a semiconductor package, in accordance with some another embodiments of the present disclosure.

FIG. 8 illustrates an exploded view of the semiconductor package shown in FIG. 7, in accordance with some another embodiments of the present disclosure.

FIG. 9 illustrates a top view of the semiconductor package shown in FIG. 7, in accordance with some another embodiments of the present disclosure.

FIGS. 10A to 10C illustrate perspective views of a first metallization layer, a second metallization layer and a third metallization layer, respectively, in the semiconductor package shown in FIG. 7, in accordance with some another embodiments of the present disclosure.

FIG. 11 illustrates a perspective view of a redistribution structure connecting an external connector of a semiconductor package, in accordance with some alternative embodiments of the present disclosure.

FIG. 12 illustrates an exploded view of the semiconductor package shown in FIG. 11, in accordance with some alternative embodiments of the present disclosure.

FIG. 13 illustrates a top view of the semiconductor package shown in FIG. 11, in accordance with some alternative embodiments of the present disclosure.

FIGS. 14A to 14C illustrate perspective views of a first metallization layer, a second metallization layer and a third metallization layer, respectively, in the semiconductor package shown in FIG. 11, in accordance with some alternative embodiments of the present disclosure.

FIG. 15 illustrates a top view of a first metallization layer, in the semiconductor package in accordance with some embodiments of the present disclosure.

FIGS. 16A to 16C illustrate top views of several variations of a first metallization layer, in the semiconductor package in accordance with some another embodiments of the present disclosure.

FIG. 17 is a flowchart of a method for forming the semiconductor package in accordance with some embodiments.

FIGS. 18A to 18I illustrate various perspective views of forming the semiconductor package in accordance with some embodiments as described in FIG. 17.

### DETAILED DESCRIPTION OF THE DISCLOSURE

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper,” “on” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The device may be otherwise oriented (rotated 100 degrees or at other orientations) and the spatially relative descriptors used herein may likewise be interpreted accordingly.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

With the evolving of semiconductor technologies, semiconductor chips/dies are becoming increasingly smaller. In the meantime, more functions need to be integrated into the semiconductor dies. Accordingly, the semiconductor dies need to have increasingly greater numbers of input/output (I/O) pads packed into smaller areas, and the density of the I/O pads rises quickly over time. As a result, the packaging of the semiconductor dies becomes more difficult, which adversely affects the yield of the packaging. Fan-out package is one type of the semiconductor packages, which means the I/O pads on a die can be redistributed to a greater area than the die. The fan-out package may be used to increase the number of I/O pads packed on the surfaces of the dies.

In general, such packages are electrically tested after fabrication to ensure the quality of the packages. When performing electrical detection, the packages are detected by a detecting device, so that terminal conductive elements of the packages (such as solder balls) are electrically connected to the detecting device, thereby electrically testing the packages under test. However, such configuration may not be feasible for identifying failure of dies or inferior electrical interconnections (such as electrical over stress, EOS) at an earlier manufacturing stage or before completion of the manufacturing. For example, an electrical testing can only be performed when the package is completed. Therefore, there is a need to monitor the fabrication of the packages at an early manufacturing stage to ensure performance of the packages with reduced cost and time.

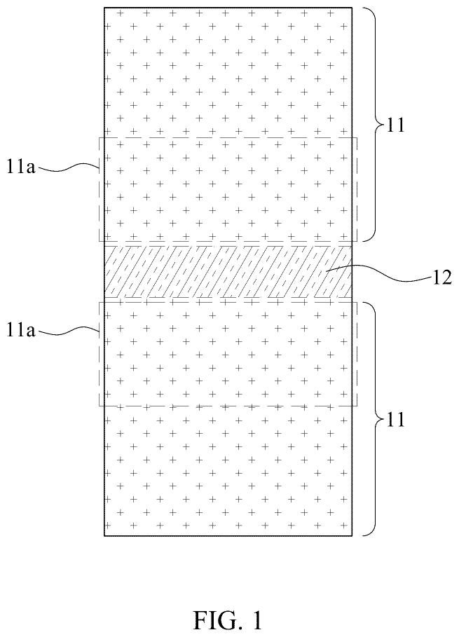

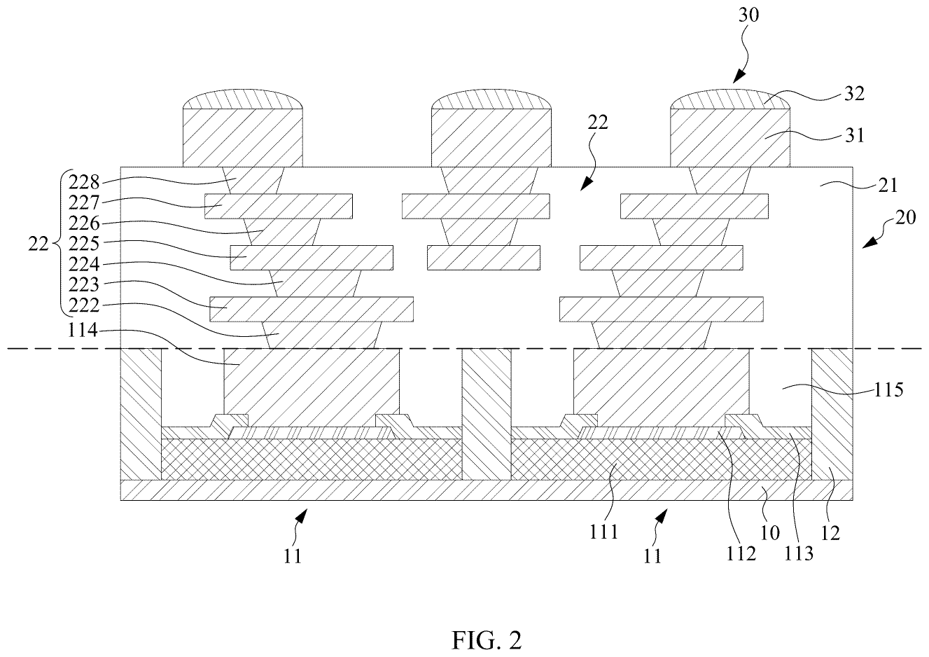

As shown in FIGS. 1 and 2, the semiconductor package structure comprises a plurality of die units 11 formed on a base layer 10, which are separated from each other through a molding structure 12; a redistribution (RDL) structure 20 stacking on the die units 11, and a plurality of external connectors 30 stacking on the redistribution structure 20.

Each of the plurality of die units 11 comprises an I/O region 11a including a die 111, a metal pad 112, a passivation layer 113, a metal pillar 114 and a top dielectric layer 115. The die 111 is formed on the base layer 10 and surrounded by the molding structure 12. In some embodiments, the die 111 may be an integrated circuit (IC) die. The IC die may be a logic die (e.g., a central processing unit (CPU) die or chip, a microcontroller die, etc.), a memory die (e.g., a dynamic random access memory (DRAM) die, a static random access memory (SRAM) die, etc.), a power management die (e.g., a power management integrated circuit (PMIC) die), a radio frequency (RF) die, a sensor die, a micro-electro-mechanical-system (MEMS) die, a signal processing die (e.g., a digital signal processing (DSP) die), a front-end die (e.g., an analog front-end (AFE) die), a bio chip, an energy harvesting chip, the like, or a combination thereof. In some embodiments, the die 111 may include passive devices. In such embodiments, the die 111 may be a zero-inductance integrated passive device (ZLIPD) die, but the disclosure is not limited thereto.

The metal pad 112 is formed on the die 111 and partially covers an upper surface of the die 111. The metal pads 112 may be aluminum pads or aluminum-copper pads, or may include other metals. In some embodiments, the metal pad 112 may be electrically connected to devices in the die 111. The passivation layer 113 is formed on the upper surface of the die 111 uncovered by the metal pad 112 and covers an edge portion of the metal pad 112 so as to expose at least a portion of an upper surface of the metal pad 112. The passivation layer 113 may be formed of a non-porous material. In accordance with some embodiments of the present disclosure, the passivation layer 113 is a composite layer comprising a silicon oxide layer (not shown), and a silicon nitride layer (not shown) over the silicon oxide layer. In alternative embodiments, passivation layer 113 comprises un-doped silicate glass (USG), silicon oxynitride, and/or the like. The passivation layer 113 may be formed by a single layer with the same material as shown in FIG. 2. Alternatively, the passivation layer 113 may be formed by two or more layers including different materials.

The metal pillar 114 stacks on and is electrically coupled to the metal pad 112. The metal pillar 114 may include copper, a copper alloy, or other metal-containing conductive materials. The top dielectric layer 115 is formed on the passivation layer 113 and surrounds the metal pillar 114 so as to be filled in a gap between the metal pillar 114 and the molding structure 12 described below. In some embodiments, an upper surface of the metal pillar 114 is aligned with an upper surface of the top dielectric layer 115. The top dielectric layer 115 may also include portions covering and protecting the metal pillar 114. The top dielectric layers 115 may be formed of a polymer such as polybenzoxazole (PBO) or polyimide in accordance with some embodiments of the present disclosure.

The molding structure 12 is formed on the base layer 10 toward the redistribution structure 20 and surround the die units 11. The molding structure 12 abuts the die 111, the passivation layer 113, a metal pillar 114 and the top dielectric layer 115. In some embodiments, the molding structure 12 may include resins such as epoxy, but the disclosure is not limited thereto. In some embodiments, the molding structure 12 may include one or more catalysts to accelerate curing of the resins. In some embodiments, the molding structure 12 may include other materials, such as flame retardants, adhesion promoters, ion traps, and/or stress relievers. The top of the molding structure 12 may be aligned with the upper surface of the metal pillar 114 and the upper surface of the top dielectric layer 115.

The redistribution structure 20 comprises a dielectric layer 21 and a plurality of metal stacks 22. The dielectric layer 21 is formed on the die units 11 and over the molding structure 12. In some embodiments, the dielectric layer 21 may be formed of low-k dielectric materials. The dielectric constant (k values) of the low-k dielectric materials may be less than about 2.8, or less than about 2.5, for example. In some embodiments, the dielectric layer 21 is formed of a polymer, which may also be a photo-sensitive material such as polybenzoxazole (PBO), polyimide, benzocyclobutene (BCB), or the like, which may be easily patterned using a photo lithography process. In some alternative embodiments, the dielectric layer 21 may be formed of a nitride such as silicon nitride, an oxide such as silicon oxide, phosphosilicate glass (PSG), borosilicate Glass (BSG), boron-doped phosphosilicate glass (BPSG), or the like.

The plurality of metal stacks 22 are formed in the dielectric layer 21 and respectively on the exposed upper surface of the metal pads 112. Each of the plurality of metal stack 22 comprises at least two via portions (including a first via portion 222, a second via portion 224, a third via portion 226 and a fourth via portion 228 as shown in FIG. 2), and at least one metallization layer (including a first metallization layer 223, a second metallization layer 225, a third metallization layer 227 as shown in FIG. 2) stacking along a direction away from the base layer 10.

The via portions 222, 224, 226 and the metallization layers 223, 225, 227 may be formed of copper, a copper alloy, or other metal-containing conductive materials. The via portions 222, 224, 226 and metallization layers 223, 225, 227 may be formed using single damascene and/or dual damascene processes. For example, the first via portion 222 and the first metallization layer 223 may be formed using single damascene and/or dual damascene processes; the second via portion 224 and the second metallization layer may be formed using single damascene and/or dual damascene processes; the third via portion 226 and the third metallization layer 227 may be formed using single damascene and/or dual damascene processes.

The plurality of external connectors 30 respectively stack on the plurality of metal stacks 22. Each of the plurality of external connectors 30 comprises a metal pillar 31 and a solder cap 32. The metal pillars 31 are formed on the fourth via portions 228 of the plurality of metal stacks 22. In some exemplary embodiments, the metal pillar 31 is formed of a non-solder material that does not melt in reflow processes for melting solder. For example, the metal pillar 31 may be formed of copper or a copper alloy. The solder cap 32 is formed on a top of the metal pillar 31, wherein solder cap 32 may be formed of a Sn—Ag alloy, a Sn—Cu alloy, a Sn—Ag—Cu alloy, or the like, and may be lead-free solder caps or lead-containing solder caps. In some exemplary embodiments, the entire metal pillar 31 is formed of a homogenously metallic material, with the solder cap 32 contacting the metal pillars 31. In alternative embodiments, there may be additional metal layers formed as conformal layers contacting the top and a sidewall of metal pillar 31.

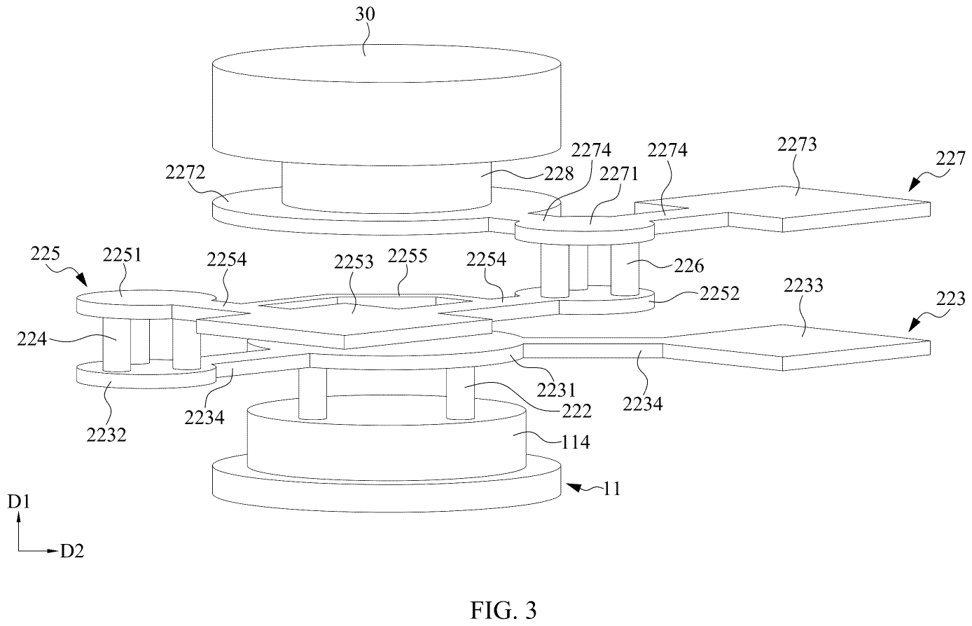

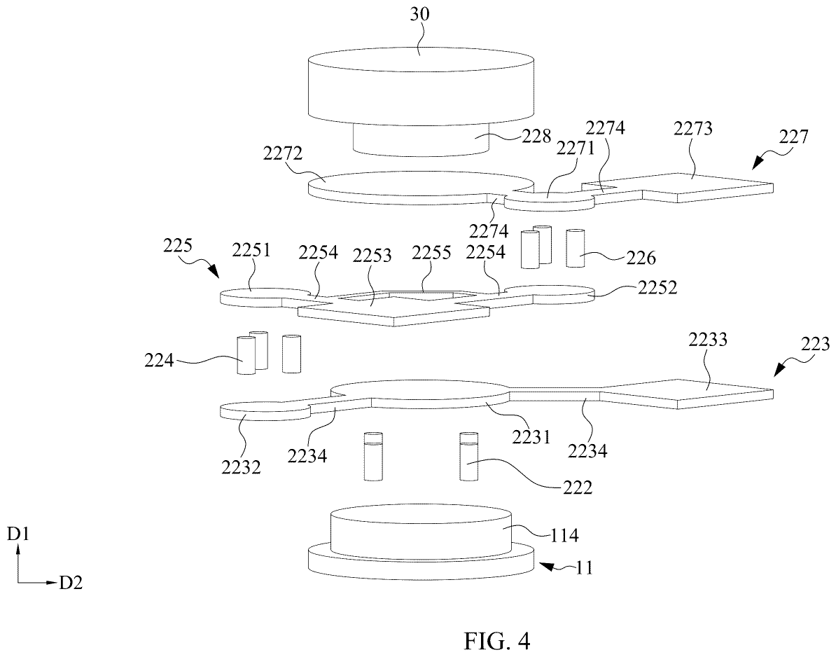

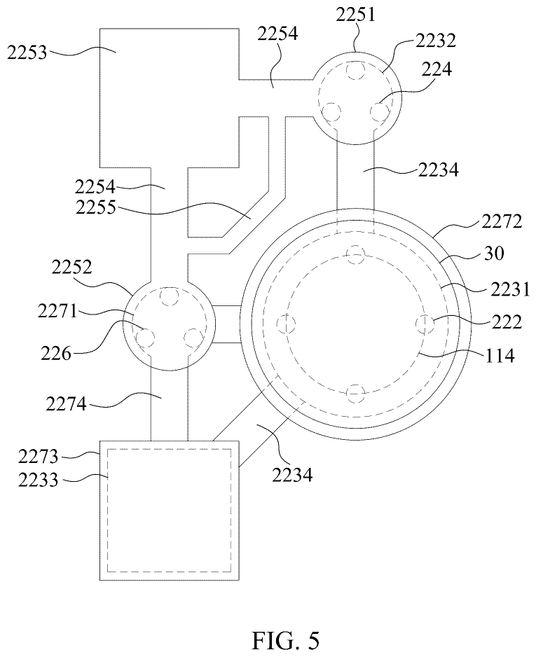

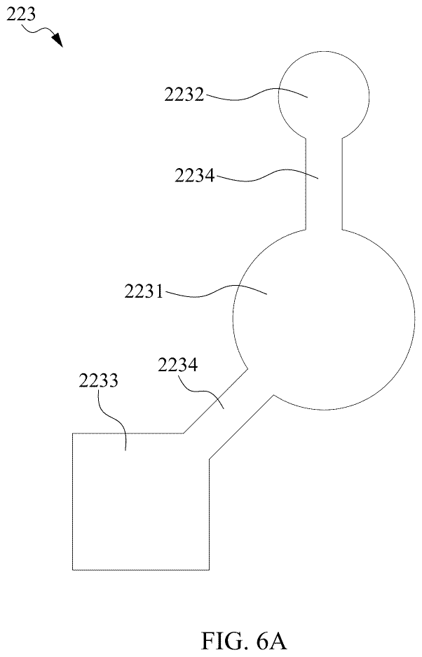

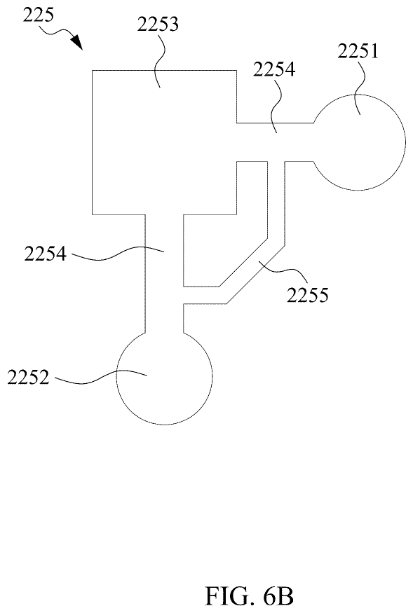

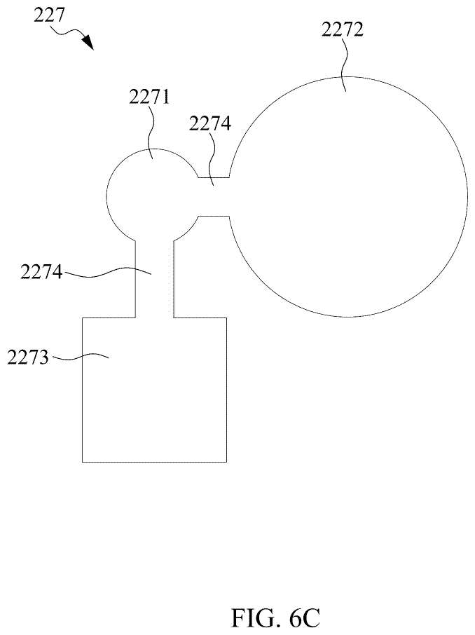

As shown in FIGS. 3 to 5, there are three metallization layers in the redistribution structure 20, including a first metallization layer 223, a second metallization layer 225, a third metallization layer 227. With further reference to FIG. 6A, the first metallization layer 223 has at least one first metallization group including a first signal pad (such as an input/output (I/O) pads) 2231, a first connecting pad 2232, a first testing pad 2233 and first connecting lines 2234. The first signal pad 2231 stacks on and electrically connects the metal pillar 114 through the first via portion 222 including, for example, one or more vias along a first direction D1. The first connecting pad 2232 electrically connects the first signal pad 2231 through the first connecting line 2234 along a second direction D2 perpendicular to the first direction D1. The first testing pad 2233 also electrically connects the first signal pad 2231 through the first connecting line 2234 along the second direction D2. After fabrication of the first metallization layer 223, a verification testing can be performed on the first testing pad 2233 using a probe/probe card.

With further reference to FIG. 6B, the second metallization layer 225 has at least one second metallization group including a second signal pad (such as I/O pads) 2251, a second connecting pad 2252, a second testing pad 2253, second connecting lines 2254 and a by-pass metal line 2255. The second signal pad 2251 stacks on and electrically connects the first connecting pad 2232 through the second via portion 224 including, for example, one or more vias along the first direction D1. The second testing pad 2253 electrically connects the second signal pad 2251 through one of the second connecting lines 2254 along the second direction D2 and also connects the second connecting pad 2252 through the other of the second connecting lines 2254 along the second direction D2. The second signal pad 2251 and the second connecting pad 2252 electrically connect with each other through the by-pass metal line 2255 along the second direction D2. In some embodiments, two terminal ends of the by-pass metal line 2255 may connect both the second connecting lines 2254 so as to electrically connect the second signal pad 2251 and the second connecting pad 2252. In some alternative embodiments, two terminal ends of the by-pass metal line 2255 may directly connect the second signal pad 2251 and the second connecting pad 2252, respectively. After fabrication of the second metallization layer 225, a verification testing can be performed on the second testing pad 2253 using a probe/probe card, which can be identical to that used to perform the verification testing on the first testing pad 2233. Since the second signal pad 2251 and the second connecting pad 2252 electrically connects to each other through the second testing pad 2253 and the second connecting lines 2254 (that is, the second testing pad 2253 connects both the second signal pad 2251 and the second connecting pad 2252), once the second testing pad 2253 is worn out after the verification testing, the second signal pad 2251 can still electrically connect the second connecting pad 2252 through the by-pass metal line 2255.

With further reference to FIG. 6C, the third metallization layer 227 has at least one third metallization group including a third signal pad (such as an input/output (I/O) pads) 2271, a third connecting pad 2272, a third testing pad 2273 and third connecting lines 2274. The third signal pad 2271 stacks on and electrically connects the second connecting pad 2252 through the third via portion 226 including, for example, one or more vias along the first direction D1. The third connecting pad 2272 electrically connects the third signal pad 2271 through the third connecting line 2274 along the second direction D2. The third testing pad 2273 also electrically connects the third signal pad 2271 through the third connecting line 2274 along the second direction D2. After fabrication of the third metallization layer 227, a verification testing can be performed on the third testing pad 2273 using a probe/probe card, which can be identical to that used to perform the verification testing on the first testing pad 2233 and/or the second testing pad 2253.

The external connector 30 electrically connects the third connecting pad 2272 through the fourth via portion 228 along the first direction D1 including, for example, one or more vias.

In some embodiments with reference to FIGS. 3 to 6, the layout of the second metallization layer 225 is different from that of the first metallization layer 223 and that of the third metallization layer 227 due to the second testing pad 2253 connecting both the second signal pad 2251 and the second connecting pad 2252 and thus the by-pass metal line 2255, which is required. In some embodiments, the second testing pad 2253 is offset from the first testing pad 2233, and the third testing pad 2273 is offset from the second testing pad 2253.

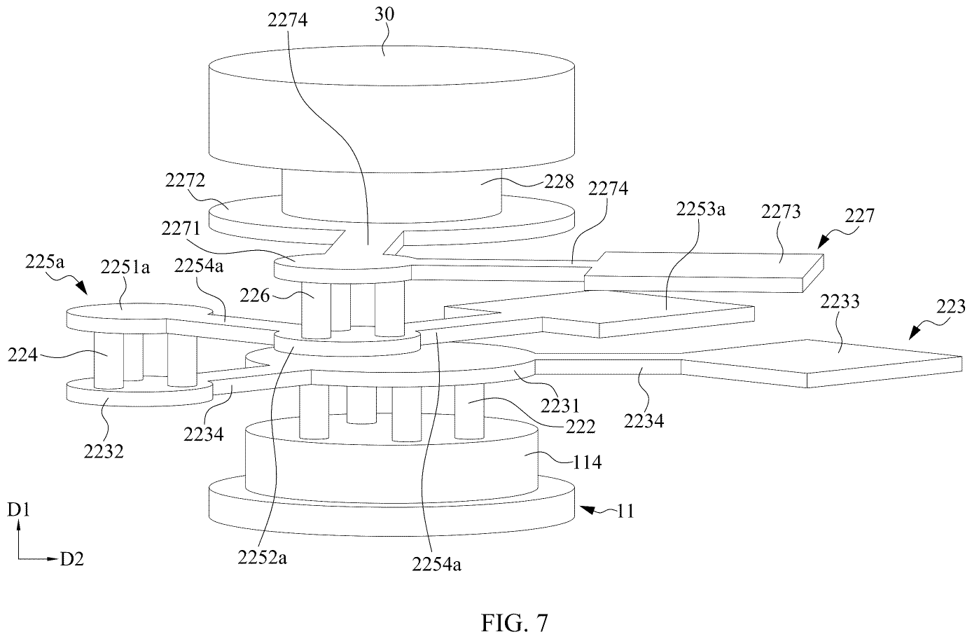

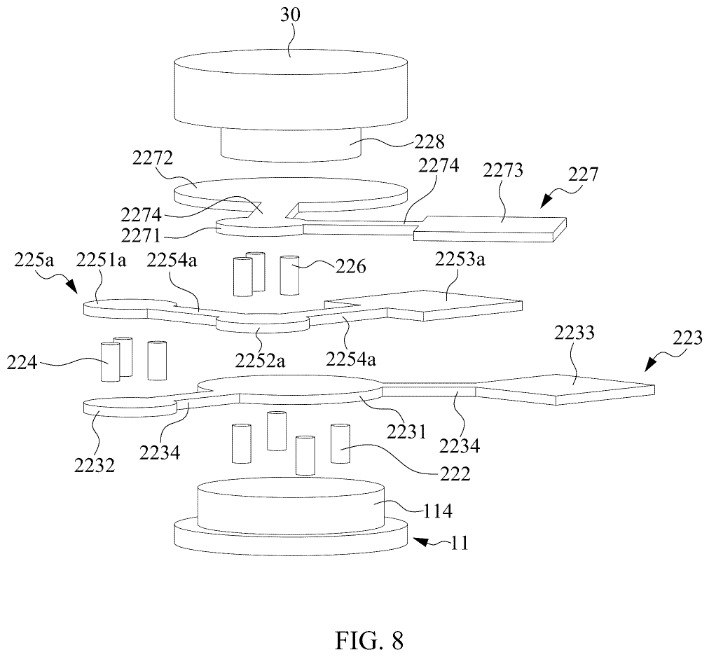

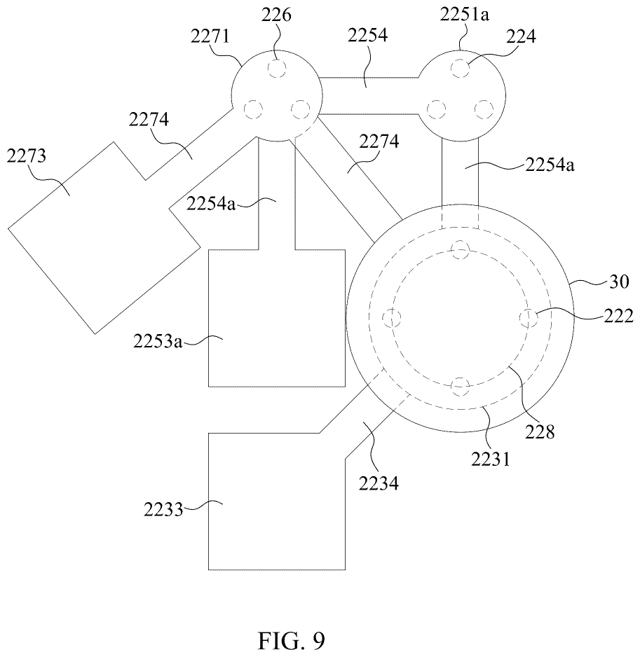

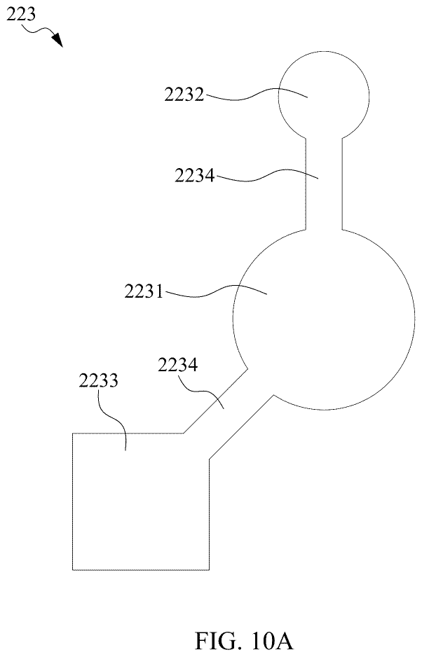

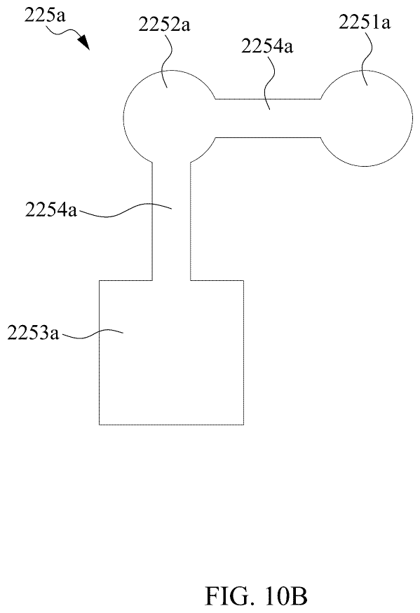

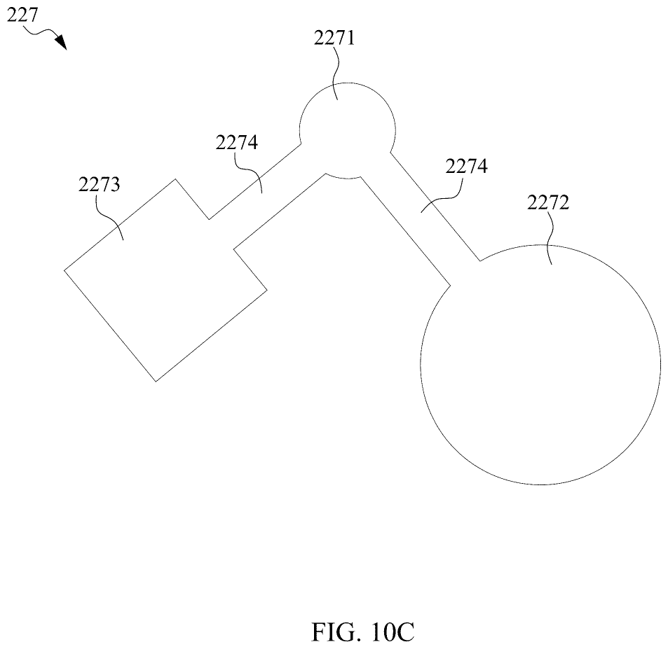

In some another embodiments with reference to FIGS. 7 to 10, the second metallization layer 225a has a second signal pad (such as I/O pads) 2251, a second connecting pad 2252, a second testing pad 2253 and second connecting lines 2254. The second signal pad 2251 stacks on and electrically connects the first connecting pad 2232 through the second via portion 224 including, for example, one or more vias along the first direction D1. The second connecting pad 2252 electrically connects the second signal pad 2251 through the second connecting line 2254 along the second direction D2. The second testing pad 2253 electrically connects the second connecting pad 2252 through the second connecting line 2254 along the second direction. Since the second signal pad 2251 and the second connecting pad 2252 directly connects with each other through one of the second connecting lines 2254 without passing through the second testing pad 2253, a by-pass metal line is not required.

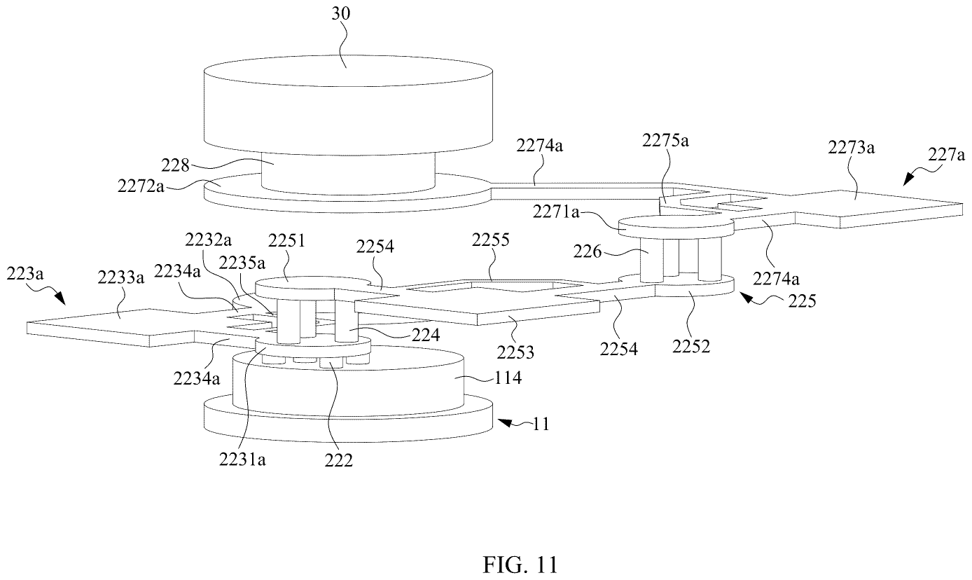

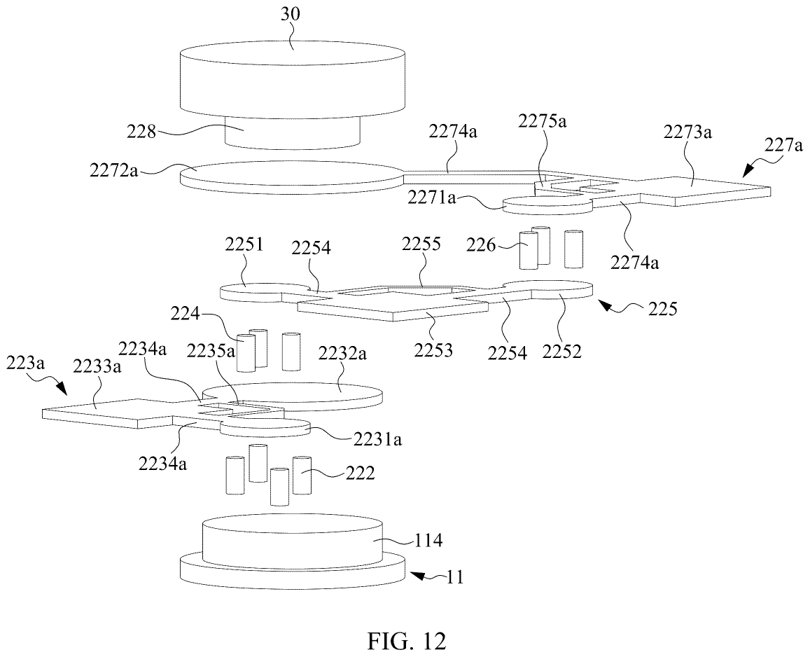

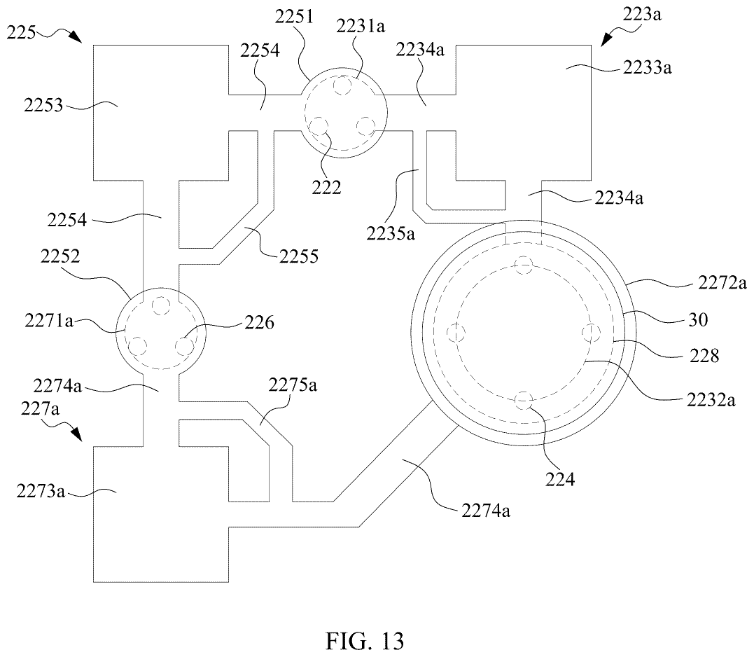

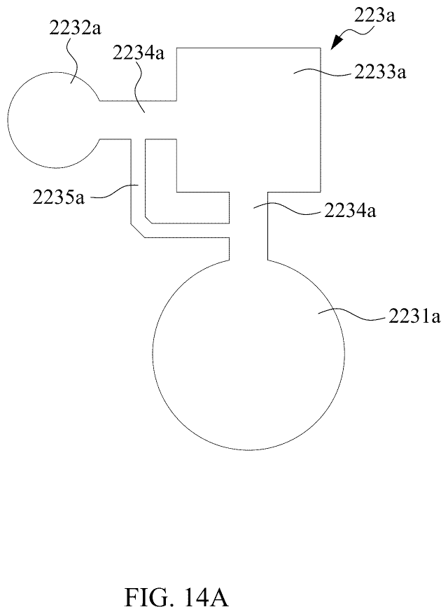

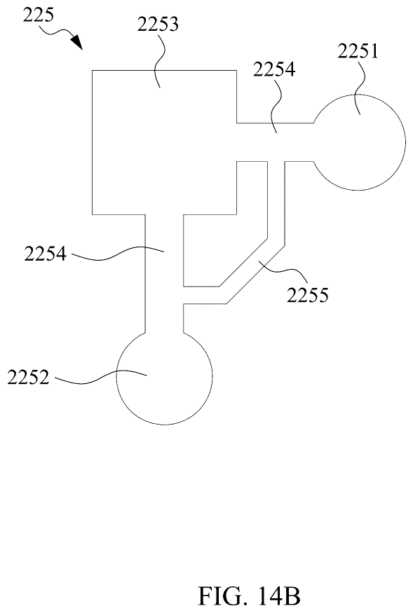

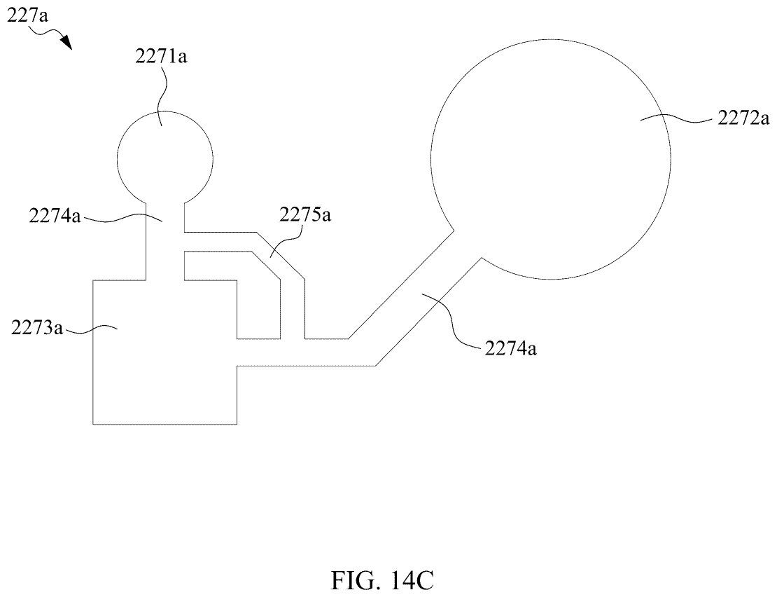

In some alternative embodiments as shown in FIGS. 11 to 14, all the metallization layers 223a, 225, 227a have by-pass metal lines 2235a, 2255, 2275a. With reference to FIG. 14A, the first metallization layer 223a has a first signal pad (such as I/O pads) 2231a, a first connecting pad 2232a, a first testing pad 2233a, first connecting lines 2234a and a by-pass metal line 2235a. The first signal pad 2231a stacks on and electrically connects the metal pillar 114 through the first via portion 222 including, for example, one or more vias along the first direction D1. The first testing pad 2233a electrically connects the first signal pad 2231a through one of the first connecting lines 2234a along the second direction D2 and also connects the first connecting pad 2232a through the other of the first connecting lines 2234a along the second direction D2. The first signal pad 2231a and the first connecting pad 2232a electrically connect with each other through the by-pass metal line 2235a. In some embodiments, two terminal ends of the by-pass metal line 2235a may connect both the first connecting lines 2234a so as to electrically connect the first signal pad 2231a and the first connecting pad 2232a. In some alternative embodiments, two terminal ends of the by-pass metal line 2235a may directly connect the first signal pad 2231a and the first connecting pad 2232a, respectively.

With further reference to FIG. 14B, the second metallization layer 225 may be identical or similar to that shown in FIG. 6B; therefore, repeated descriptions are omitted for brevity.

With reference to FIG. 14C, the third metallization layer 227a has a third signal pad (such as I/O pads) 2271a, a third connecting pad 2272a, a third testing pad 2273a, third connecting lines 2274a and a by-pass metal line 2275a. The third signal pad 2271a electrically connects the second connecting pad 2252 through the third via portion 226 including, for example, one or more vias. The third testing pad 2273a electrically connects the third signal pad 2271a through one of the third connecting lines 2274a and also connects the third connecting pad 2272a through the other of the third connecting lines 2274a. The third signal pad 2271a and the third connecting pad 2272a electrically connect with each other through the by-pass metal line 2275a. In some embodiments, two terminal ends of the by-pass metal line 2275a may connect both the third connecting lines 2274a so as to electrically connect the third signal pad 2271a and the third connecting pad 2272a. In some alternative embodiments, two terminal ends of the by-pass metal line 2275a may directly connect the third signal pad 2271a and the third connecting pad 2272a, respectively.

In view of FIGS. 1 to 6, the first signal pad 2231, the second signal pad 2251 and the third signal pad 2271 may have top cross-sections with the same shape or with different shapes, including circular shape, triangular shape, rectangular shape (including square shape), polygonal shape or the like. As shown in FIGS. 6A to 6C, for example, each of the first signal pad 2231, the second signal pad 2251 and the third signal pad 2271 has a circular top cross-section. The first connecting pad 2232, the second connecting pad 2252 and the third connecting pad 2272 may have top cross-sections with the same shape or with different shapes, including circular shape, triangular shape, rectangular shape, polygonal shape or the like. Each of the first connecting pad 2232, the second connecting pad 2252 and the third connecting pad 2272 may have a top cross-section identical to or different from the top cross-section of each of the first signal pad 2231, the second signal pad 2251 and the third signal pad 2271.

As shown in FIGS. 6A to 6C, for example, each of the first connecting pad 2232, the second connecting pad 2252 and the third connecting pad 2272 has a circular top cross-section. The first testing pad 2233, the second testing pad 2253 and the third testing pad 2273 may have top cross-sections with the same shape or with different shapes, including circular shape, triangular shape, rectangular shape, polygonal shape or the like. In some embodiments, each of the first connecting pad 2232, the second connecting pad 2252 and the third connecting pad 2272 may have a top cross-section identical to or different from the top cross-section of each of the first signal pad 2231, the second signal pad 2251 and the third signal pad 2271. In some embodiments, each of the first connecting pad 2232, the second connecting pad 2252 and the third connecting pad 2272 may have a top cross-section identical to or different from the top cross-section of the first connecting pad 2232, the second connecting pad 2252 and the third connecting pad 2272. As shown in FIGS. 6A to 6C, for example, each of the first testing pad 2233, the second testing pad 2253 and the third testing pad 2273 has a rectangular top cross-section.

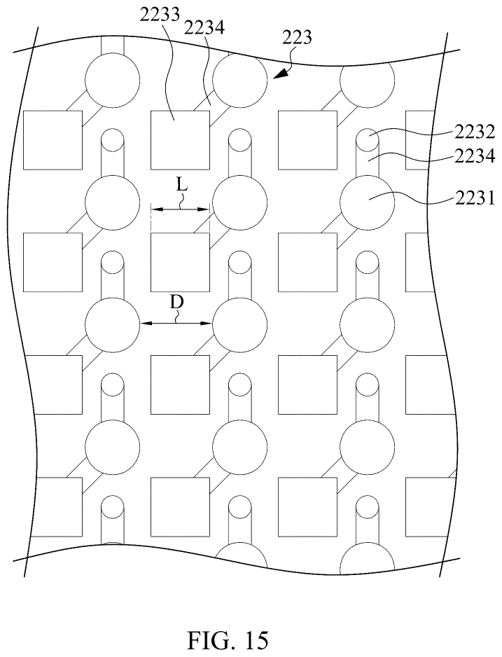

With reference to FIG. 15, taking the first metallization layer 223 as an example, the first metallization layer 223 has several first metallization groups. The first testing pad 2233 has a rectangular top cross-section. The first testing pad 2233 of one of the first metallization groups is located in a space surrounded by several first metallization groups. A narrowest distance D between two adjacent first signal pads 2231 is greater than a length L of the first testing pad 2233. In some embodiments, a ratio of D to L may range from about 100:99 to about 10:1. In some embodiments, the ratio of D to L may range from about 10:9 to about 5:1. In some embodiments, the ratio of D to L may range from about 4:3 to about 4:1. In some embodiments, the narrowest distance D between two adjacent first signal pads 2231 may be equal to or larger than 50 μm. In some embodiments, the narrowest distance D between two adjacent first signal pads 2231 may range from about 50 μm to about 150 μm. In some embodiments, the narrowest distance D between two adjacent first signal pads 2231 may range from about 70 μm to about 125 μm. In some embodiments, the narrowest distance D between two adjacent first signal pads 2231 may range from about 85 μm to about 100 μm. In some embodiments, the length L of the first testing pad 2233 may be less than about 100 μm. In some embodiments, the length L of the first testing pad 2233 may be less than about 75 μm. In some embodiments, the length L of the first testing pad 2233 may be less than about 50 μm.

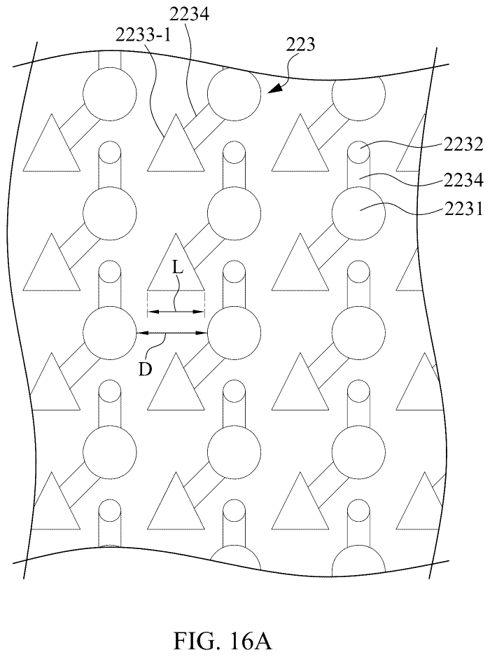

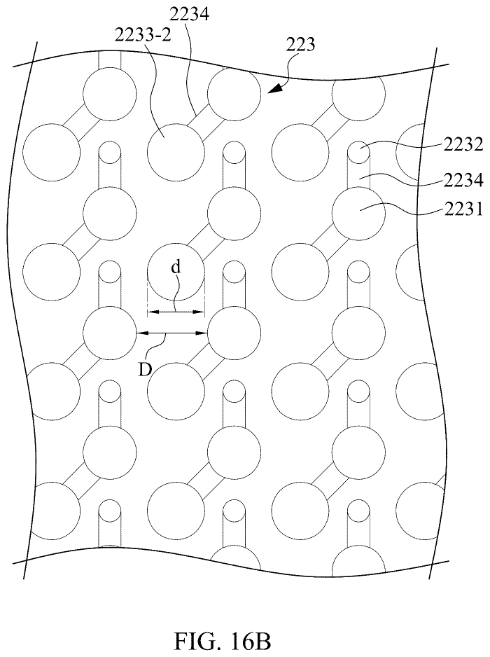

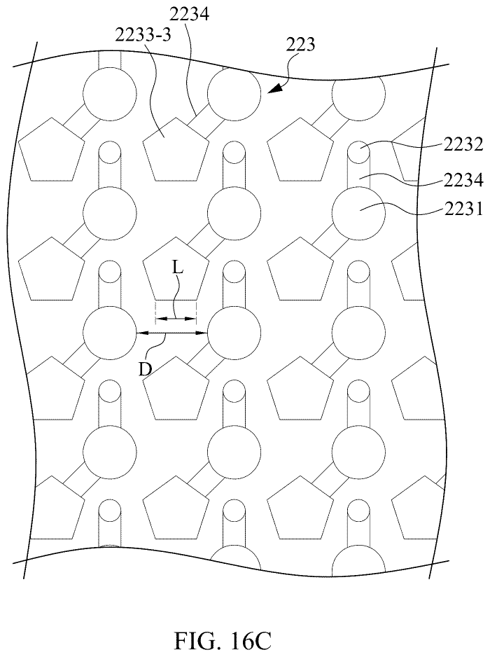

In some embodiments as shown in FIG. 16A, the first testing pad 2233-1 has a triangular top cross-section. A narrowest distance D between two adjacent first signal pads 2231 is greater than a length L of one side of the first testing pad 2233-1. In some embodiments, a ratio of D to L may range from about 100:99 to about 10:1. In some embodiments, the ratio of D to L may range from about 10:9 to about 5:1. In some embodiments, the ratio of D to L may range from about 4:3 to about 4:1. In some embodiments as shown in FIG. 16B, the first testing pad 2233-2 has a circular top cross-section. A narrowest distance D between two adjacent first signal pads 2231 is greater than a diameter d of the first testing pad 2233-2. In some embodiments, a ratio of D to d may range from about 100:99 to about 10:1. In some embodiments, the ratio of D to d may range from about 10:9 to about 5:1. In some embodiments, the ratio of D to d may range from about 4:3 to about 4:1. In some embodiments as shown in FIG. 16C, the first testing pad 2233-3 has a pentagonal top cross-section. A narrowest distance D between two adjacent first signal pads 2231 is greater than a length L of a side of the first testing pad 2233-3. In some embodiments, a ratio of D to L may range from about 100:99 to about 10:1. In some embodiments, the ratio of D to L may range from about 10:9 to about 5:1. In some embodiments, the ratio of D to L may range from about 4:3 to about 4:1. These are, of course, merely examples and are not intended to be limiting. Any other shapes of the first testing pad can also be applied to meet layout design, required demand and so on.

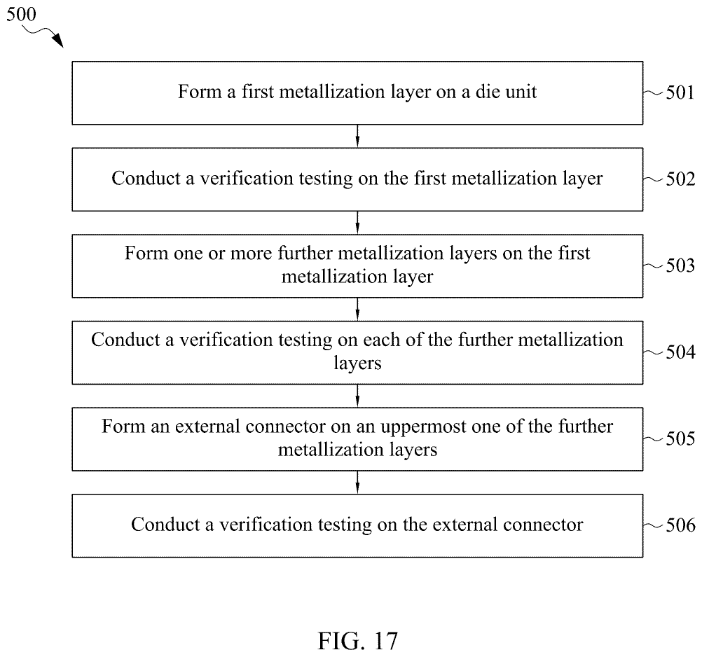

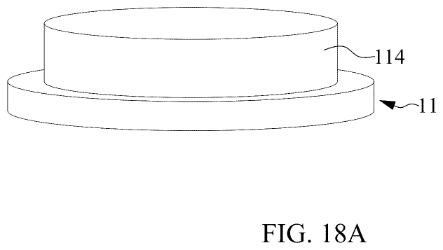

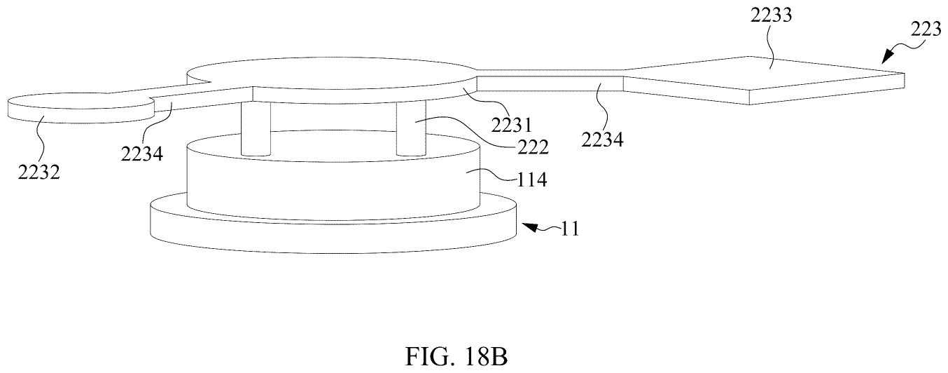

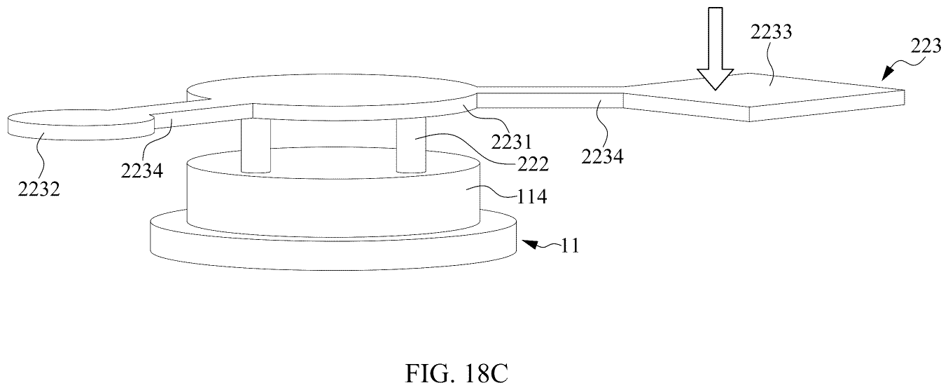

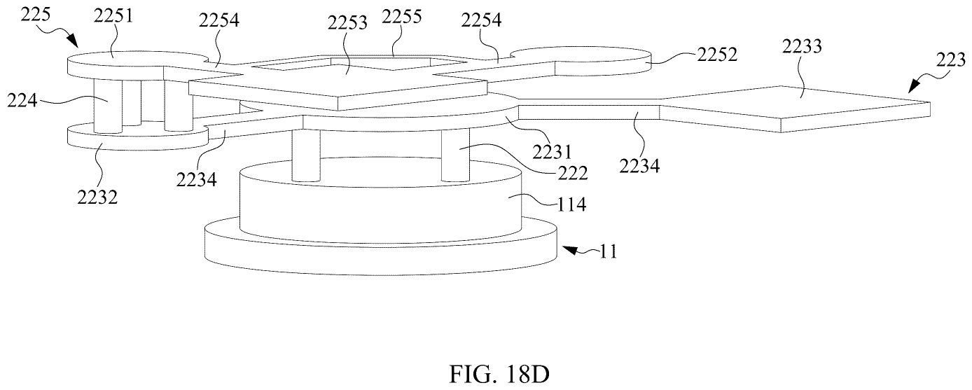

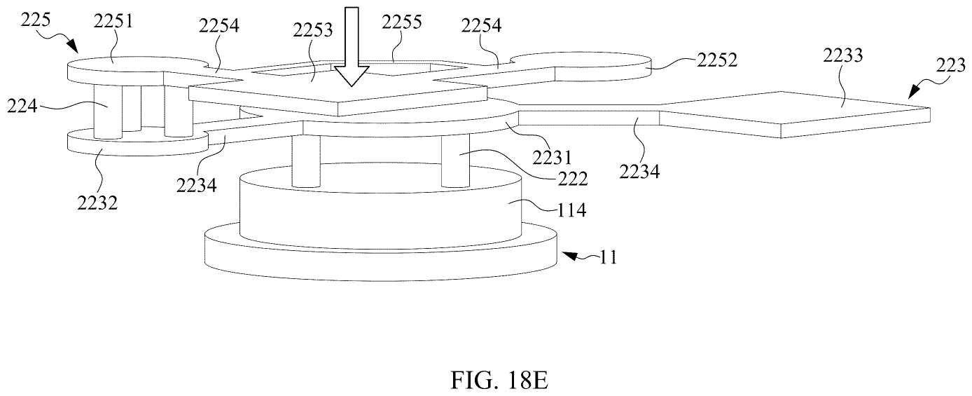

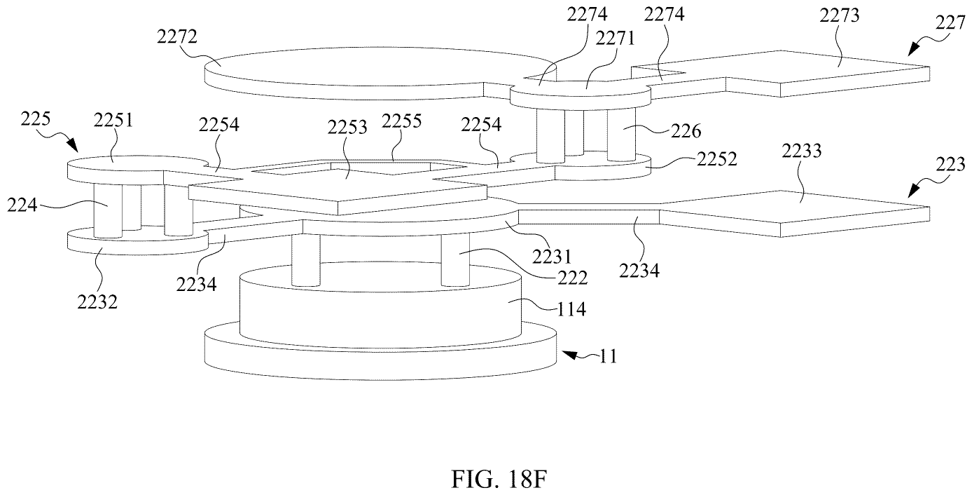

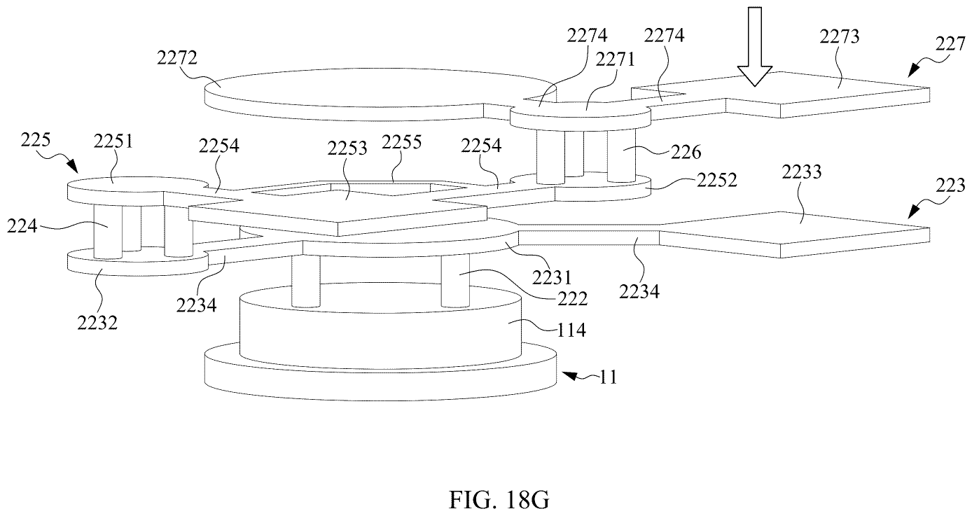

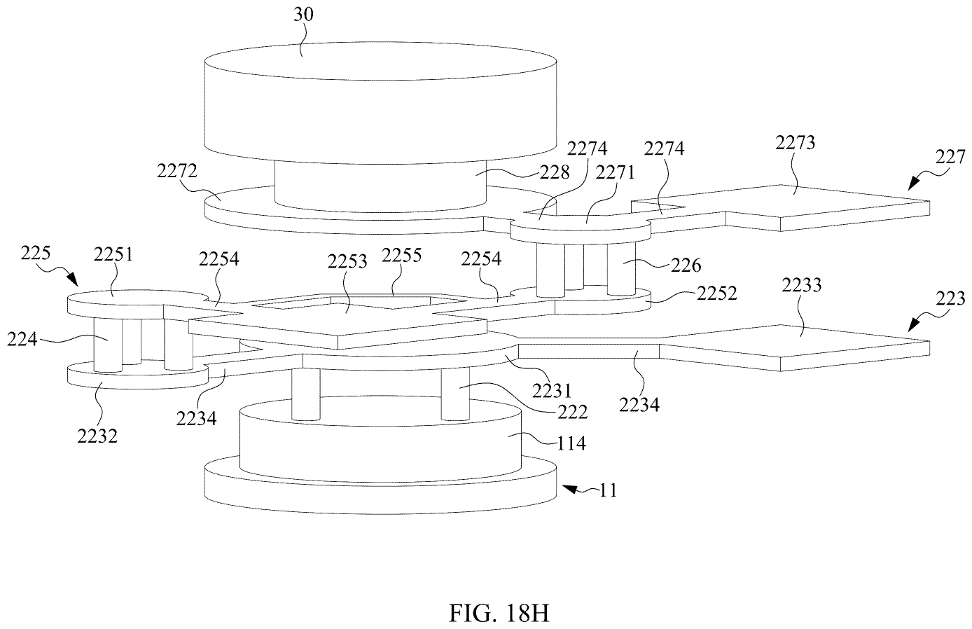

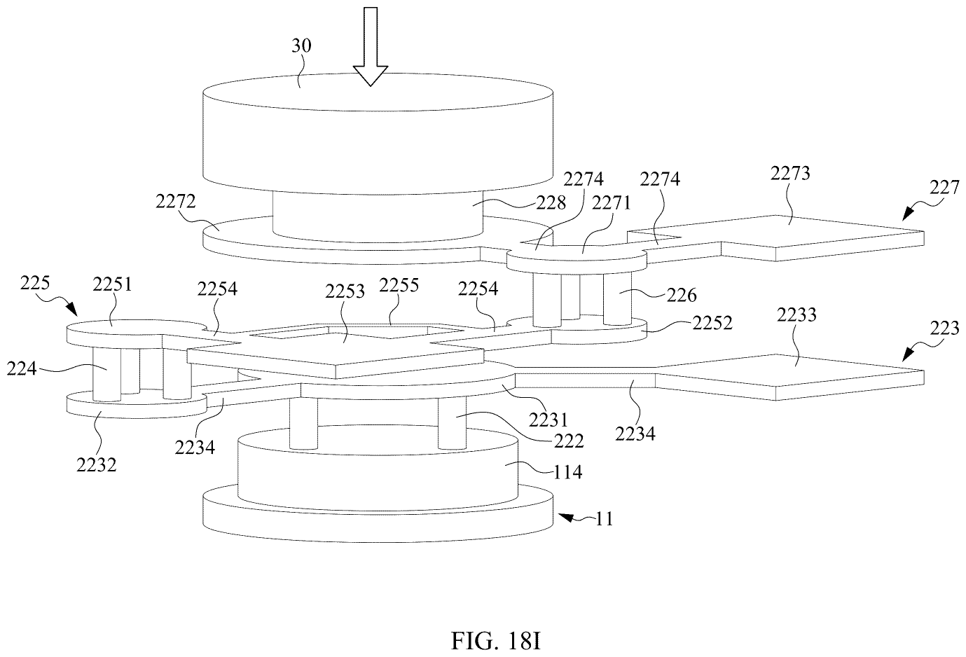

FIG. 17 is a flowchart representing a method 500 for forming a semiconductor package according to various aspects of the present disclosure. In some embodiments, the method 500 for forming the semiconductor package includes a number of operations (501, 502, 503, 504, 505, 506). The method 500 for forming the semiconductor package will be further described according to one or more embodiments. It should be noted that the operations of the method 500 may be rearranged or otherwise modified within the scope of the various aspects. It should further be noted that additional processes may be provided before, during, and after the method 500, and that some other processes may be only briefly described herein. FIGS. 18A to 18I are diagrammatic perspective views illustrating various stages in the method 500 for forming the connecting structure according to aspects of one or more embodiments of the present disclosure.

With reference to FIGS. 18A and 18B, method 500 begins at operation 501 where a first metallization layer 23 stacks on the die unit 11 through a metal pillar 114 and a first via portion 222. The die unit 11 is formed on a base layer 10 and comprises a die 111, a metal pad 112, a passivation layer 113, the metal pillar 114 and a top dielectric layer 115 as shown in FIG. 2; therefore, repeated descriptions are omitted for brevity. The first metallization layer 223 stacks on and electrically connects the metal pillar 114 through the first via portion 222 including, for example, one or more vias. The first metallization layer 223 and the first via portion 222 can be formed by any suitable operation such as single or dual damascene formation operations, and descriptions of such details are omitted for brevity. The first metallization layer 223 comprises a first signal pad (such as an input/output (I/O) pads) 2231, a first connecting pad 2232, a first testing pad 2233 and first connecting lines 2234, which are formed integrally through a suitable mask. The first signal pad 2231, the first connecting pad, 2232 the first testing pad 2233 and the first connecting lines 2234 can be similar to those described above in view of FIG. 2; therefore, repeated descriptions of such details are omitted for brevity.

At operation 502 as shown in FIG. 18C, a verification testing is conducted (represented by the arrow in FIG. 18C) by electrically connecting a probe card (not shown) to the first testing pad 2233. In some embodiments, the probe card is electrically connected to the first testing pad 2233 through a probe card terminal. In some embodiments, the probe card includes a power supply and is embedded with a chip or a functional circuitry such as a memory, a dynamic random access memory (DRAM), a flash memory, a NAND flash memory or a serial peripheral interface (SPI) memory.

The method 500 continues with operation 503 and operation 504 where one or more further metallization layers stacks on the first metallization layer 223 and a verification testing is conducted on each of the further metallization layers. As shown in FIG. 18D, a second metallization layer 225 stacks on and electrically connects the first metallization layer 223 through a second via portion 224 including, for example, one or more vias. The second metallization layer 225 and the second via portion 224 can be formed by any suitable operation such as single or dual damascene formation operations, and descriptions of such details are omitted for brevity. The second metallization layer 225 comprises a second signal pad (such as an input/output (I/O) pads) 2251, a second connecting pad 2252, a second testing pad 2253, second connecting lines 2254 and a by-pass metal line 2255, which are formed integrally through a suitable mask. The second signal pad 2251, the second connecting pad 2252, the second testing pad 2253, the second connecting lines 2254 and the by-pass metal line 2255 can be similar to those described above in view of FIG. 2; therefore, repeated descriptions of such details are omitted for brevity.

As shown in FIG. 18E, a verification testing is conducted (represented by the arrow in FIG. 18E) by electrically connecting a probe card (not shown) to the second testing pad 2253. The probe card used to test the second testing pad 2253 may be identical to or different from that used to test the first testing pad 2233.

As shown in FIG. 18F, a third metallization layer 227 stacks on and electrically connects the second metallization layer 225 through a third via portion 226 including, for example, one or more vias. The third metallization layer 227 and the third via portion 226 can be formed by any suitable operation such as single or dual damascene formation operations, and descriptions of such details are omitted for brevity. The third metallization layer 227 comprises a third signal pad (such as an input/output (I/O) pads) 2271, a third connecting pad 2272, a third testing pad 2273 and third connecting lines 2274, which are formed integrally through a suitable mask. The third signal pad 2271, the third connecting pad 2272, the third testing pad 2273 and the third connecting lines 2274 can be similar to those described above in view of FIG. 2; therefore, repeated descriptions of such details are omitted for brevity.

As shown in FIG. 18G, a verification testing is conducted (represented by the arrow in FIG. 18G) by electrically connecting a probe card (not shown) to the third testing pad 2273. The probe card used to test the third testing pad 2273 may be identical to or different from that used to test the first testing pad 2233 and/or the second testing pad 2253.

At operation 505 as shown in FIG. 18H, an external connector 30 stacks on and electrically connects the third metallization layer 227 through a fourth via portion 228 including, for example, one or more vias. The external connector 30 and the fourth via portion 228 can be formed by any suitable operation such as single or dual damascene formation operations, and descriptions of such details are omitted for brevity. The external connectors 30 may comprise a metal pillar 31 and a solder cap 32 as shown in FIG. 2; therefore, repeated descriptions of such details are omitted for brevity.

At operation 506 as shown in FIG. 18I, a verification testing is conducted (represented by the arrow in FIG. 18I) by electrically connecting a probe card (not shown) to the external connector 30. The probe card used to test the external connector 30 may be identical to or different from that used to test the first testing pad 2233 and/or the second testing pad 2253 and/or third testing pad 2273. In some embodiments, only one probe card is needed to test the first testing pad 2233, the second testing pad 2253, third testing pad 2273 and the external connector 30, which can reduce process complexity.

A verification testing can be conducted during the fabrication of the redistribution structure 20 due to the formation of a testing pad in each metallization layer so that defects (such as electrical over stress, EOS or other process defects) can be monitored and identified at an earlier stage. Additionally, in some embodiments, the second testing pad 2253 is offset from the first signal pad 2231, and the third testing pad 2273 is offset from the second signal pad 2251 and the first signal pad 2231. Accordingly, influence to the underlying signal pads (i.e., the first signal pad 2231 and the second signal pad 2251) due to stresses generated from the probe card during the verification testing is mitigated.

In some embodiments, a semiconductor package comprises a redistribution structure stacking on a die unit and comprising a first metallization layer electrically connecting the die unit through a first via portion, wherein the first metallization layer comprises a first signal pad, a first connecting pad and a first testing pad electrically connect with each other; a second metallization layer stacking on and electrically connecting the first metallization layer through a second via portion, wherein the second metallization layer comprises a second signal pad, a second connecting pad and a second testing pad electrically connect with each other; and a third metallization layer stacking on and electrically connecting the second metallization layer through a third via portion, wherein the third metallization layer comprises a third signal pad, a third connecting pad and a third testing pad electrically connect with each other; and an external connector stacking on and electrically connecting the third metallization layer through a fourth via portion.

In some embodiments, a semiconductor package comprises a plurality of metal stacks stacking on a plurality of die units and each of the plurality of metal stacks comprising at least one metallization layer electrically connecting at least one of the plurality of die units through a via portion and comprising a signal pad, a connecting pad and a testing pad electrically connecting with each other.

In some embodiments, a method for forming a semiconductor package comprises forming a first metallization layer on a die unit; conducting a verification testing on the first metallization layer; forming one or more further metallization layers on the first metallization layer; conducting a verification testing on each of the further metallization layers; forming an external connector on an uppermost one of the further metallization layers; and conducting a verification testing on the external connector.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

Moreover, the scope of the present application is not intended to be limited to the particular embodiments of the process, machine, manufacture, composition of matter, means, methods and steps described in the specification. As one of ordinary skill in the art will readily appreciate from the disclosure of the present invention, processes, machines, manufacture, compositions of matter, means, methods, or steps, presently existing or later to be developed, that perform substantially the same function or achieve substantially the same result as the corresponding embodiments described herein may be utilized according to the present invention. Accordingly, the appended claims are intended to include within their scope such processes, machines, manufacture, compositions of matter, means, methods, or steps.

1. A semiconductor package, comprising:
a redistribution structure stacking on a die unit and comprising:
a first metallization layer electrically connecting the die unitthrough a first via portion, wherein the first metallization layer comprises a first signal pad, a first connecting pad and a first testing pad electrically connect with each other;
a second metallization layer stacking on and electrically connecting the first metallization layer through a second via portion, wherein the second metallization layer comprises a second signal pad, a second connecting pad and a second testing pad electrically connect with each other; and
a third metallization layer stacking on and electrically connecting the second metallization layer through a third via portion, wherein the third metallization layer comprises a third signal pad, a third connecting pad and a third testing pad electrically connect with each other; and
an external connector stacking on and electrically connecting the third metallization layer through a fourth via portion.

2. The semiconductor package of claim 1, wherein
the first signal pad stacks on and electrically connects the die unit through the first via portion along a first direction and electrically connects the first connecting pad and the first testing pad through two respective first connecting lines along a second direction perpendicular to the first direction;
the second signal pad stacks on and electrically connects the first connecting pad through the second via portion along the first direction;
the second testing pad electrically connects the second signal pad and the second connecting pad through two respective second connecting lines along the second direction;
the second connecting lines electrically connect with each other through a by-pass metal line;
the third signal pad stacks on and electrically connects the second connecting pad through the third via portion along the first direction and electrically connects the third connecting pad and third testing pad through two respective third connecting lines along the second direction; and
the external connector stacks on and electrically connects the third connecting pad through the fourth via portion along the first direction.

3. The semiconductor package of claim 1, wherein
the first signal pad stacks on and electrically connects the die unit through the first via portion along a first direction and electrically connects the first connecting pad and the first testing pad through two respective first connecting lines along a second direction perpendicular to the first direction;
the second signal pad stacks on and electrically connects the first connecting pad through the second via portion along the first direction and electrically connects the second connecting pad and second testing pad through two respective second connecting lines along the second direction;
the third signal pad stacks on and electrically connects the second connecting pad through the third via portion along the first direction and electrically connects the third connecting pad and third testing pad through two respective third connecting lines along the second direction; and
the external connector stacks on and electrically connects the third connecting pad through the fourth via portion along the first direction.

4. The semiconductor package of claim 1, wherein
the first signal pad stacks on and electrically connects the die unit through the first via portion along a first direction;
the first testing pad electrically connects the first signal pad and the second connecting pad through two respective first connecting lines along the second direction;
the first connecting lines electrically connect with each other through a first by-pass metal line;
the second signal pad stacks on and electrically connects the first connecting pad through the second via portion along the first direction;
the second testing pad electrically connects the second signal pad and the second connecting pad through two respective second connecting lines along the second direction;
the second connecting lines electrically connect with each other through a second by-pass metal line;
the third signal pad stacks on and electrically connects the second connecting pad through the third via portion along the first direction;
the third testing pad electrically connects the third signal pad and the third connecting pad through two respective third connecting lines along the second direction;
the third connecting lines electrically connect with each other through a third by-pass metal line; and
the external connector stacks on and electrically connects the third connecting pad through the fourth via portion along the first direction.

5. The semiconductor package of claim 1, wherein the first testing pad has a top cross-section, which is identical to or different from a top cross-section of the first signal pad; the second testing pad has a top cross-section, which is identical to or different from a top cross-section of the second signal pad; and the third testing pad has a top cross-section, which is identical to or different from a top cross-section of the third signal pad.

6. The semiconductor package of claim 1, wherein the first testing pad has a top cross-section, which is identical to or different from a top cross-section of the first connecting pad; the second testing pad has a top cross-section, which is identical to or different from a top cross-section of the second connecting pad; and the third testing pad has a top cross-section, which is identical to or different from a top cross-section of the third connecting pad.

7. The semiconductor package of claim 1, wherein the die unit comprises:
a die formed on a base layer and surrounded by a molding structure;
a metal pad formed on the die and partially covering an upper surface of the die;
a passivation layer formed on the upper surface of the die uncovered by the metal pad and covering an edge portion of the metal pad;
a metal pillar stacks on the metal pad; and
a top dielectric layer formed on the passivation layer and surrounding the metal pillar.

8. A semiconductor package, comprising:
a plurality of metal stacks stacking on a plurality of die units and each of the plurality of metal stacks comprising at least one metallization layer electrically connecting at least one of the plurality of die units through a via portion and comprising a signal pad, a connecting pad and a testing pad electrically connecting with each other.

9. The semiconductor package of claim 8, wherein a narrowest distance between the signal pad in one of the plurality of metal stacks and the signal pad in an adjacent one of the plurality of metal stacks is greater than a length or a diameter of the testing pad.

10. The semiconductor package of claim 9, wherein a ratio of the narrowest distance to the length or diameter of the testing pad ranges from about 100:99 to about 10:1.

11. The semiconductor package of claim 9, wherein the narrowest distance ranges from about 50 μm to about 150 μm; and the length or diameter of the testing pad is less than about 100 μm.

12. The semiconductor package of claim 8, wherein the signal pad stacks on and electrically connects the metal pillar through the first via portion along a first direction and electrically connects the connecting pad and the testing pad through two respective first connecting lines along a second direction perpendicular to the first direction.

13. The semiconductor package of claim 8, wherein
the signal pad stacks on and electrically connects the metal pillar through the first via portion along a first direction;
the testing pad electrically connects the signal pad and the connecting pad through two respective connecting lines along a second direction perpendicular to the first direction; and
the connecting lines electrically connect with each other through a by-pass metal line.

14. The semiconductor package of claim 8, wherein the testing pad has a top cross-section, which is circular, triangular, rectangular, or polygonal.

15. A method for manufacturing a semiconductor package, comprising:
forming a first metallization layer on a die unit;
conducting a verification testing on the first metallization layer;
forming one or more further metallization layers on the first metallization layer;
conducting a verification testing on each of the further metallization layers;
forming an external connector on an uppermost one of the further metallization layers; and
conducting a verification testing on the external connector.

16. The method of claim 15, wherein
the first metallization layer comprises a first signal pad, a first connecting pad and a first testing pad electrically connecting with each other, and the verification testing is conducted on the first metallization layer by connecting a first probe card with the first testing pad; and
each of the one or more further metallization layers comprises a further signal pad, a further connecting pad and a further testing pad electrically connecting with each other, and the verification testing is conducted on each of the further metallization layers by connecting a second probe card with the further testing pad.

17. The method of claim 16, wherein the first probe card is identical to or different from the second probe card.

18. The method of claim 16, wherein
the first signal pad stacks on and electrically connects a die unit through a first via portion along a first direction and electrically connects the first connecting pad and the first testing pad through two respective first connecting lines along a second direction perpendicular to the first direction;
the further signal pad stacks on and electrically connects the first connecting pad through a further via portion along the first direction;
the further testing pad electrically connects the further signal pad and the further connecting pad through two respective further connecting lines along the second direction; and
the further connecting lines electrically connect with each other through a by-pass metal line.

19. The method of claim 15, wherein
the first signal pad stacks on and electrically connects a die unit through a first via portion along a first direction and electrically connects the first connecting pad and the first testing pad through two respective first connecting lines along a second direction perpendicular to the first direction; and
the further signal pad stacks on and electrically connects the first connecting pad through a further via portion along the first direction and electrically connects the further connecting pad and the further testing pad through two respective further connecting lines along a second direction perpendicular to the first direction.

20. The method of claim 15, wherein
the first signal pad stacks on and electrically connects a die unit through a first via portion along a first direction;
the first testing pad electrically connects the first signal pad and the first connecting pad through two respective first connecting lines along the second direction; and
the first connecting lines electrically connect with each other through a first by-pass metal line;
the further signal pad stacks on and electrically connects the first connecting pad through a further via portion along the first direction;
the further testing pad electrically connects the further signal pad and the further connecting pad through two respective further connecting lines along the second direction; and
the further connecting lines electrically connect with each other through a by-pass metal line.
